(19) United States
(12) Patent Application Publication
(10) Pub. No.: US 2015/0129939 A1
(43) Pub. Date: May 14, 2015

(54) METHOD AND STRUCTURE FOR FORMING CONTACTS

(71) Applicant: International Business Machines Corporation, Armonk, NY (US)

(72) Inventors: Emre Alptekin, Wappingers Falls, NY (US); Viraj Yashawant Sardesai, Poughkeepsie, NY (US); Reinaldo Ariel Vega, Wappingers Falls, NY (US)

(73) Assignee: International Business Machines Corporation, Armonk, NY (US)

(21) Appl. No.: 14/076,903

(22) Filed: Nov. 11, 2013

(51) Int. Cl. H01L 29/417; H01L 29/66

(52) U.S. Cl. CPC H01L 29/41775; H01L 29/66553
USPC 257/288; 438/299

(57) ABSTRACT

Embodiments of the present invention provide an improved structure and method for forming high aspect ratio contacts. A horizontally formed contact etch stop layer is deposited in a narrow area where a contact is to be formed. A gas cluster ion beam (GCIB) process is used in the deposition of the horizontally formed contact etch stop layer.

### FIELD OF THE INVENTION

The present invention relates generally to semiconductor fabrication, and more particularly, to methods and structures for forming contacts on transistors.

### BACKGROUND OF THE INVENTION

The semiconductor integrated circuit (IC) industry has experienced rapid growth. In the course of the IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advances to be realized, similar developments in IC manufacturing are needed. For example, as the semiconductor industry has progressed into nanometer technology process nodes in pursuit of higher device density, higher performance, and lower costs, challenges from both fabrication and design have resulted in the development of fin-type field effect transistor (FinFET) devices. Contacts formed on the finFETs connect the finFETs to other elements, such as other transistors, diodes, capacitors, resistors, and the like, by way of back-end-of-line (BEOL) metallization levels. Thus, formation of transistor contacts is an important part of implementing integrated circuits.

### SUMMARY OF THE INVENTION

In a first aspect, embodiments of the present invention provide a semiconductor structure, comprising: a semiconductor substrate; a gate formed on the semiconductor substrate; a source/drain region formed in the semiconductor substrate and disposed adjacent to the gate; a spacer disposed on the gate; a horizontally formed contact etch stop layer disposed on the source/drain region; and a contact disposed on the source/drain region, wherein the contact traverses the horizontally formed contact etch stop layer.

In a second aspect, embodiments of the present invention provide a method of forming a semiconductor structure, comprising: forming a gate on a semiconductor substrate; forming spacers on the gate; forming a source/drain region in the semiconductor substrate adjacent to the gate; depositing a horizontally formed contact etch stop layer on the semiconductor structure; depositing an interlayer dielectric material on the semiconductor structure; forming a contact cavity in the interlayer dielectric material, wherein the contact cavity terminates at the contact etch stop layer; forming an opening in the contact etch stop layer to expose the source/drain region; and depositing a conductor in the contact cavity.

In a third aspect, embodiments of the present invention provide method of forming a semiconductor structure, comprising: forming a gate on a semiconductor substrate; forming spacers on the gate, wherein the spacers have a vertical sidewall; forming a source/drain region in the semiconductor substrate adjacent to the gate; depositing a horizontally formed contact etch stop layer on the semiconductor structure using a gas cluster ion beam deposition process, wherein the horizontally formed contact etch stop layer is substantially flat, and does not adhere to the vertical sidewall of the spacers; depositing an interlayer dielectric material on the semiconductor structure; forming a contact cavity in the interlayer dielectric material, wherein the contact cavity terminates at the contact etch stop layer; forming an opening in the contact etch stop layer to expose the source/drain region; and depositing a conductor in the contact cavity.

### BRIEF DESCRIPTION OF THE DRAWINGS

The structure, operation, and advantages of the present invention will become further apparent upon consideration of the following description taken in conjunction with the accompanying figures (FIGs.). The figures are intended to be illustrative, not limiting.

Certain elements in some of the figures may be omitted, or illustrated not-to-scale, for illustrative clarity. The cross-sectional views may be in the form of “slices”, or “near-sighted” cross-sectional views, omitting certain background lines which would otherwise be visible in a “true” cross-sectional view, for illustrative clarity.

Often, similar elements may be referred to by similar numbers in various figures (FIGs) of the drawing, in which case typically the last two significant digits may be the same, the most significant digit being the number of the drawing figure (FIG). Furthermore, for clarity, some reference numbers may be omitted in certain drawings.

FIG. 1 is a semiconductor structure at a starting point for embodiments of the present invention.

FIG. 2 is a semiconductor structure after subsequent process steps of forming gate spacers and active areas.

FIG. 3 is a semiconductor structure after a subsequent process step of depositing a horizontally formed contact etch stop layer.

FIG. 4 is a semiconductor structure after subsequent process steps of depositing an interlayer dielectric, and planarization.

FIG. 5 is a semiconductor structure after a subsequent process step of removing the horizontally formed contact etch stop layer, spacer (and hardmask) from top surfaces.

FIG. 6 is a semiconductor structure after performing a replacement metal gate (RMG) process.

FIG. 7 is a semiconductor structure after subsequent process steps of depositing additional interlayer dielectric.

FIG. 8 is a semiconductor structure after a subsequent process step of forming a contact cavity in the interlayer dielectric material.

FIG. 9 is a semiconductor structure after a subsequent process step of forming an opening in the contact etch stop layer.

FIG. 10 is a semiconductor structure after subsequent process steps of depositing a conductor in the contact cavity, and planarization.

FIG. 11 is a flowchart indicating process steps for embodiments of the present invention.

### DETAILED DESCRIPTION

Embodiments of the present invention provide an improved structure and method for forming high aspect ratio contacts. A horizontally formed contact etch stop layer is deposited in a narrow area where a contact is to be formed. A gas cluster ion beam (GCIB) process is used in the deposition of the horizontally formed contact etch stop layer.

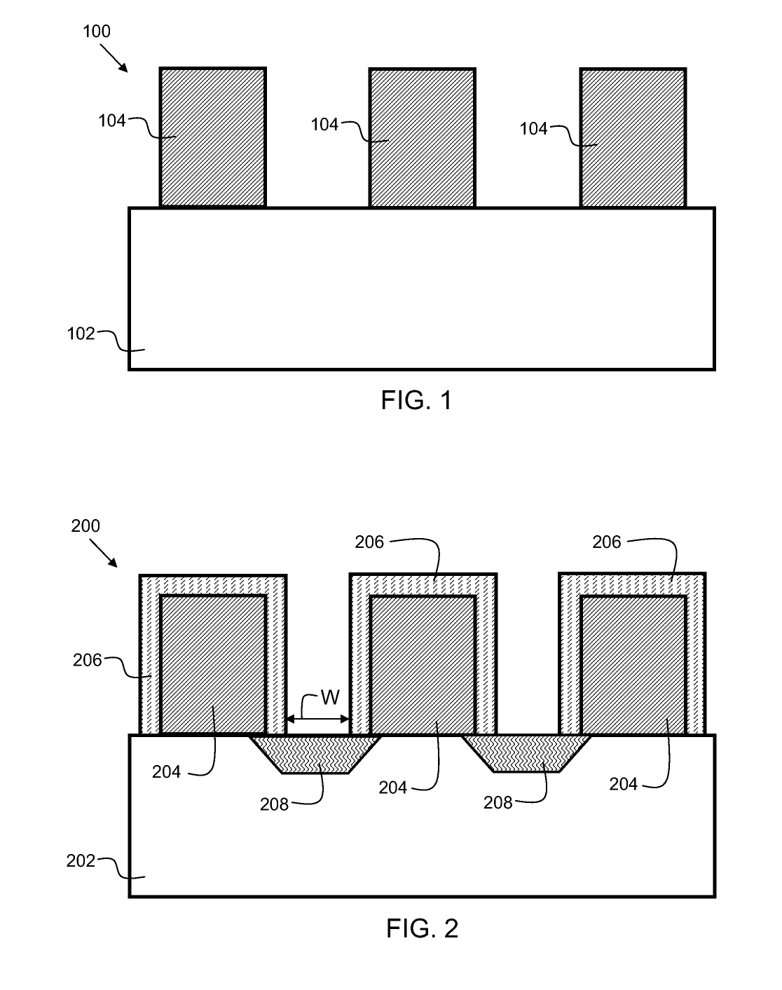

FIG. 1 is a semiconductor structure 100 at a starting point for embodiments of the present invention. Semiconductor structure 100 comprises a semiconductor substrate 102. In embodiments, semiconductor substrate 102 is a bulk semiconductor substrate, such as a silicon substrate. While a bulk structure is illustrated in FIG. 1, some embodiments of the present invention may utilize similar structure on a silicon-on-insulator (SOI) or other substrates. Other commonly practiced processes for device isolation such as shallow trench isolation or equivalent have not been included in the figures for simplicity. Disposed on substrate 102 is a plurality of gates, indicated generally as 104. A thin dielectric layer (not shown) may be disposed between each gate 104, and the substrate 102. In embodiments, gates 104 are comprised of polysilicon. Other embodiments of the present invention can utilize metal gates, by using a replacement metal gate (RMG) process. In the case of an RMG process, gates 104 are subsequently replaced with metal gates at a future processing step.

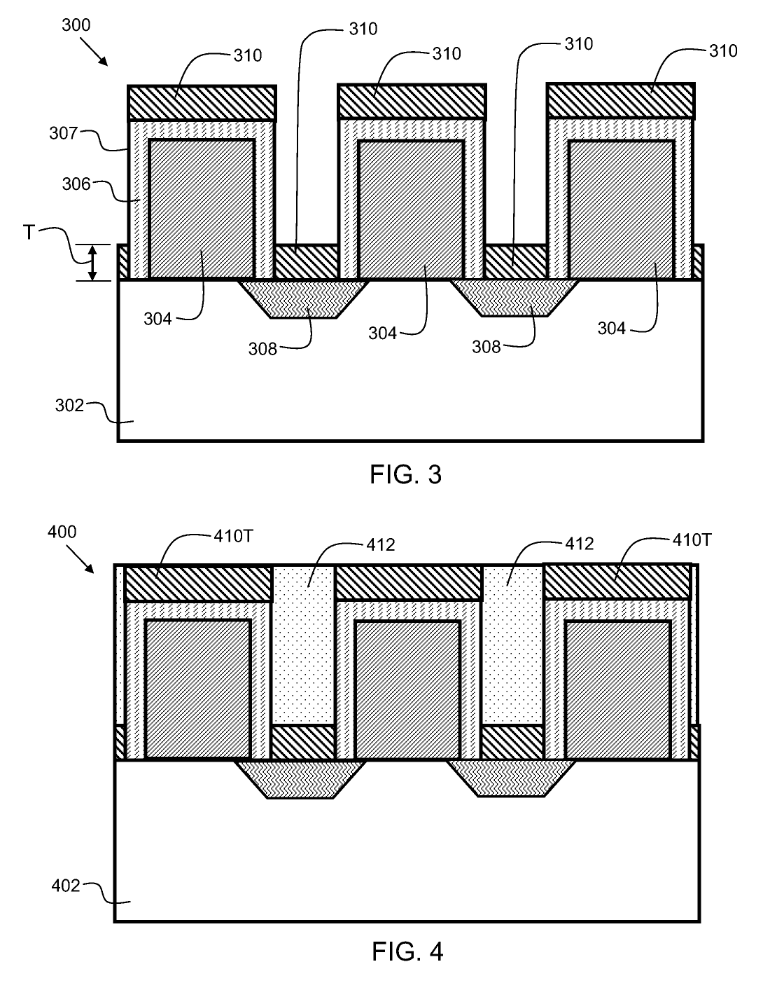

FIG. 2 is a semiconductor structure 200 after subsequent process steps of forming gate spacers 206 and source/drain regions 208. As stated previously, similar elements may be referred to by similar numbers in various figures (FIGs) of the drawing, in which case typically the last two significant digits may be the same. For example, semiconductor substrate 202 of FIG. 2 is similar to semiconductor substrate 102 of FIG. 1. Spacers 206 may be comprised of oxide, such as silicon oxide, nitride, such as silicon nitride, or a combination of multiple layers of oxides and nitrides. Active areas form source/drain regions 208. In embodiments, the source/drain regions 208 are formed in the semiconductor substrate 202 and disposed adjacent to the gate 204. In embodiments, the source/drain regions 208 are formed by ion implantation, in-situ doping of epitaxial semiconductor regions, or combinations thereof. While the source/drain regions 208 are illustrated as being formed within substrate 202, some embodiments of the present invention may utilize a raised source/drain (RSD) structure. In embodiments, the width W between neighboring gates (including the spacers) may range from about 10 nanometers to about 20 nanometers. This narrow space makes it challenging to form high aspect ratio contacts. For the purposes of this disclosure, a high aspect ratio contact is one having a height to width ratio of 5 or more.

FIG. 3 is a semiconductor structure 300 after a subsequent process step of depositing a horizontally formed contact etch stop layer 310. Horizontally formed contact etch stop layer 310 deposits on horizontal surfaces, but does not deposit on substantially vertical surfaces such as spacer sidewalls 307. That is, horizontally formed contact etch stop layer 310 is substantially flat, and does not adhere to the vertical sidewall 307 of the spacers 306. In embodiments, contact etch stop layer 310 is deposited via a gas cluster ion beam (GCIB) deposition process. More particularly, the horizontally formed etch stop layer deposits on horizontal surfaces (zero degrees) with a thickness T. For angled surfaces (greater than zero), the horizontally formed etch stop layer is thinner than T, and the thickness t is a function of the angle A such that t=f(A). This occurs with surfaces at angles up to around 75 degrees, beyond which point, the thickness t is negligible. Hence, for epitaxial surfaces that grow faceted along crystalline planes, the horizontally formed etch stop layer still provides sufficient coverage.

As the term is used herein, gas-clusters are nano-sized aggregates of materials that are gaseous under conditions of standard temperature and pressure. Such gas-clusters typically consist of aggregates of from a few to several thousand molecules loosely bound to form the gas-cluster. The gas-clusters can be ionized by electron bombardment or other means, permitting them to be formed into directed beams of controllable energy. The larger sized gas-cluster ions are often the most useful because of their ability to carry substantial energy per gas-cluster ion, while yet having only modest energy per molecule. The gas-clusters disintegrate on impact, with each individual molecule carrying only a small fraction of the total gas-cluster ion energy. Consequently, the impact effects of large gas-cluster ions are substantial, but are limited to a very shallow surface region. This makes gas-cluster ions effective for a variety of surface modification processes, without the tendency to produce deeper subsurface damage characteristic of conventional monomer ion beam processing. Many useful surface-processing effects can be achieved by bombarding surfaces with GCIBs. These processing effects include, but are not necessarily limited to, cleaning, smoothing, etching, doping, and film formation or growth.

In embodiments, contact etch stop layer 310 is comprised of silicon nitride. In other embodiments, contact etch stop layer 310 is comprised of an oxide, such as hafnium oxide. In yet other embodiments, the etch stop liner is selected from the group consisting of: aluminum oxide, zirconium silicate, hafnium silicate, hafnium silicon nitride, lanthanum oxide, zirconium oxide, cerium oxide, titanium dioxide, and tantalum oxide.

The contact etch stop layer 310 has a thickness T. In embodiments, thickness T ranges from about 3 nanometers to about 15 nanometers. In particular, when the contact etch stop layer 310 is comprised of silicon nitride, a thickness ranging from about 6 nanometers to about 12 nanometers provides suitable margin for a selective etch process. In practice, a finite amount of etch stop material is consumed during a selective etch process. Therefore, if thickness T is too thin, the etch stop layer 310 could be breached, causing irregularities in the contact formation. These irregularities can induce unwanted device variability, and adversely affect product yield. The trouble with a conventional conformal nitride is that the narrow width (W in FIG. 2) of the contact area prevents a sufficiently thick film without having issues due to deposition on the spacer sidewalls, making a very narrow, and possibly irregularly shaped area for which to make contact with source/drain regions 308. By utilizing a horizontally formed contact etch stop layer 310, the aforementioned problems are mitigated. With other materials, the thickness T can be reduced. For example, if contact etch stop layer 310 is comprised of hafnium oxide, then in some embodiments, the thickness T ranges from about 4 nanometers to about 8 nanometers.

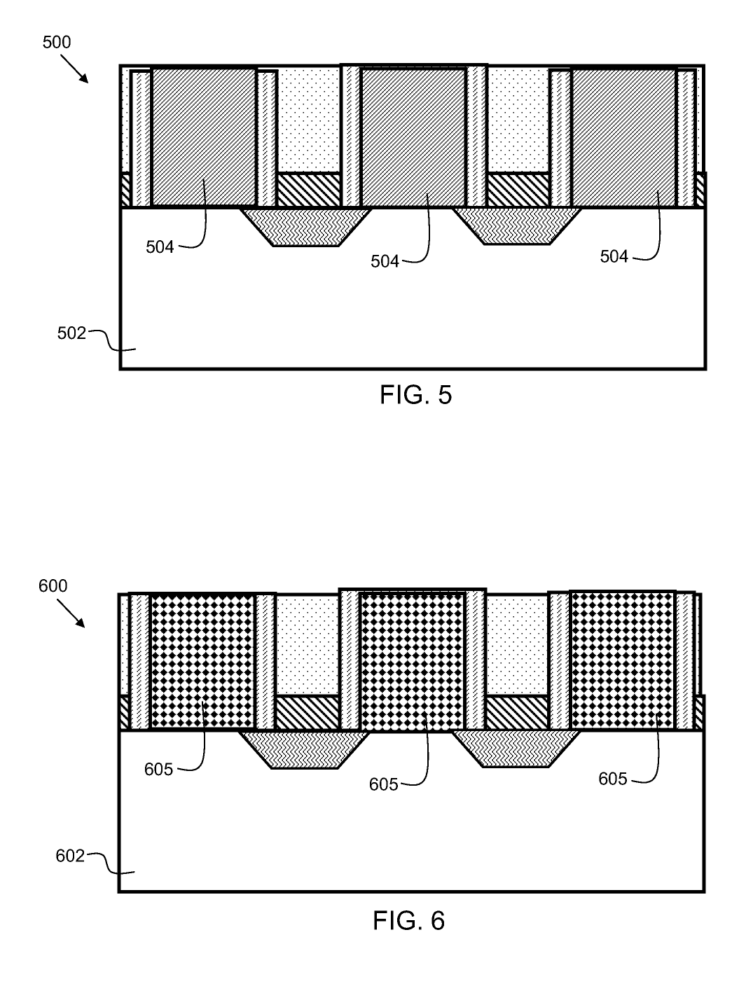

FIG. 4 is a semiconductor structure 400 after subsequent process steps of depositing an interlayer dielectric 412, and planarization to the level of the top portion of the contact etch stop layer, indicated as 410T. The interlayer dielectric 412 may include an oxide, such as silicon oxide. In embodiments, the planarization is performed with a chemical mechanical polish (CMP) process.

FIG. 5 is a semiconductor structure 500 after a subsequent process step of removing the horizontally formed contact etch stop layer from top surfaces (compare with 410T of FIG. 4) and other insulators above gate conductor exposing the top of the polysilicon gates 504. In embodiments, this removal is done with either by reactive ion etch or chemical mechanical polish (CMP). Embodiments of the present invention can utilize polysilicon gates (gate first process) or a replacement metal gate (RMG) process (gate last process). In the case of a gate first process, the exposed polysilicon of gate 504 can be silicided to facilitate forming contacts on the gate.

FIG. 6 shows a semiconductor structure 600 after performing a replacement metal gate process. In case of replacement metal gate processes, the polysilicon is removed (e.g. by etching) and replacement metal gate layers along with suitable high K layer dielectrics are deposited and subsequently planarized with chemical mechanical polish (CMP) to form replacement metal gates 605.

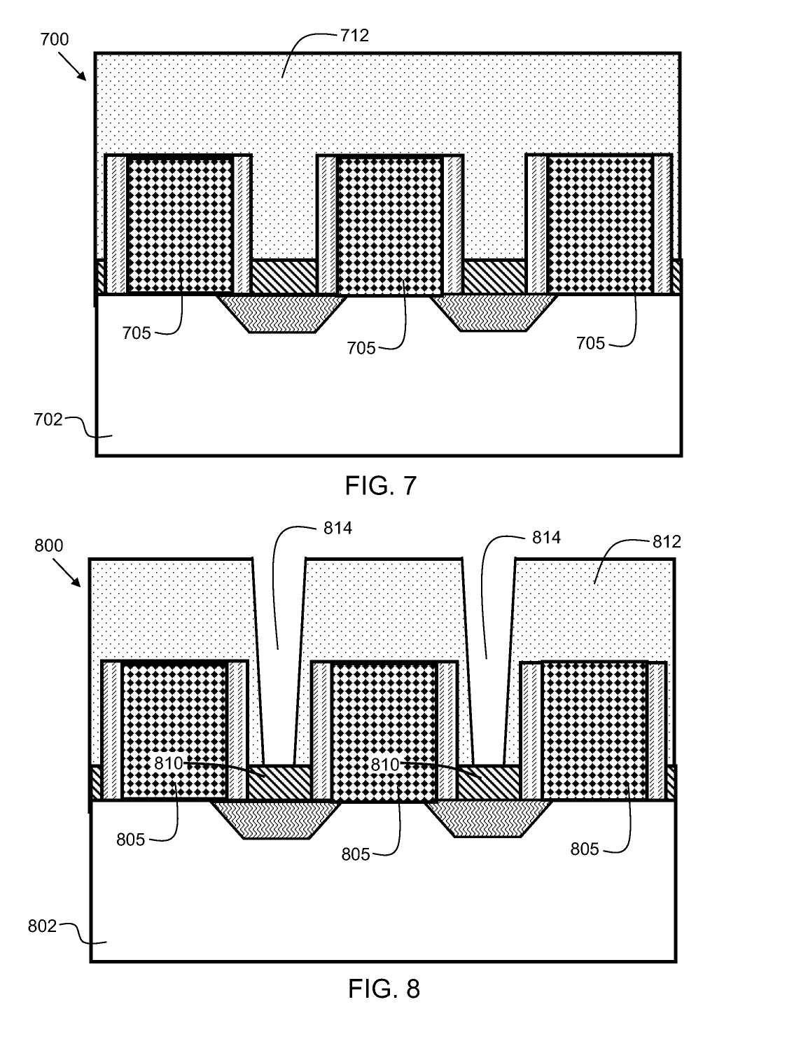

FIG. 7 is a semiconductor structure 700 after subsequent process steps of depositing additional interlayer dielectric 712, optionally followed by another planarization. In embodiments, the additional interlayer dielectric 712 is also formed of silicon oxide. A recess may then be used to achieve a desired thickness. Optionally, a planarization process, such as a chemical mechanical polish is performed to achieve a planar surface. In some embodiments, an additional capping layer comprised of silicon nitride (not shown) may be disposed on the interlayer dielectric 712.

FIG. 8 is a semiconductor structure 800 after a subsequent process step of forming a contact cavity 814 in the interlayer dielectric material 812. In embodiments, the contact cavities 814 are formed using an anisotropic etch process, such as a reactive ion etch (RIE) process. The etch is selective such that it terminates on the contact etch stop layer 810. In other embodiments, contact cavities may be formed by multiple patterning process and masking steps and selective etch steps all terminating on horizontally formed contact etch stop layer 810.

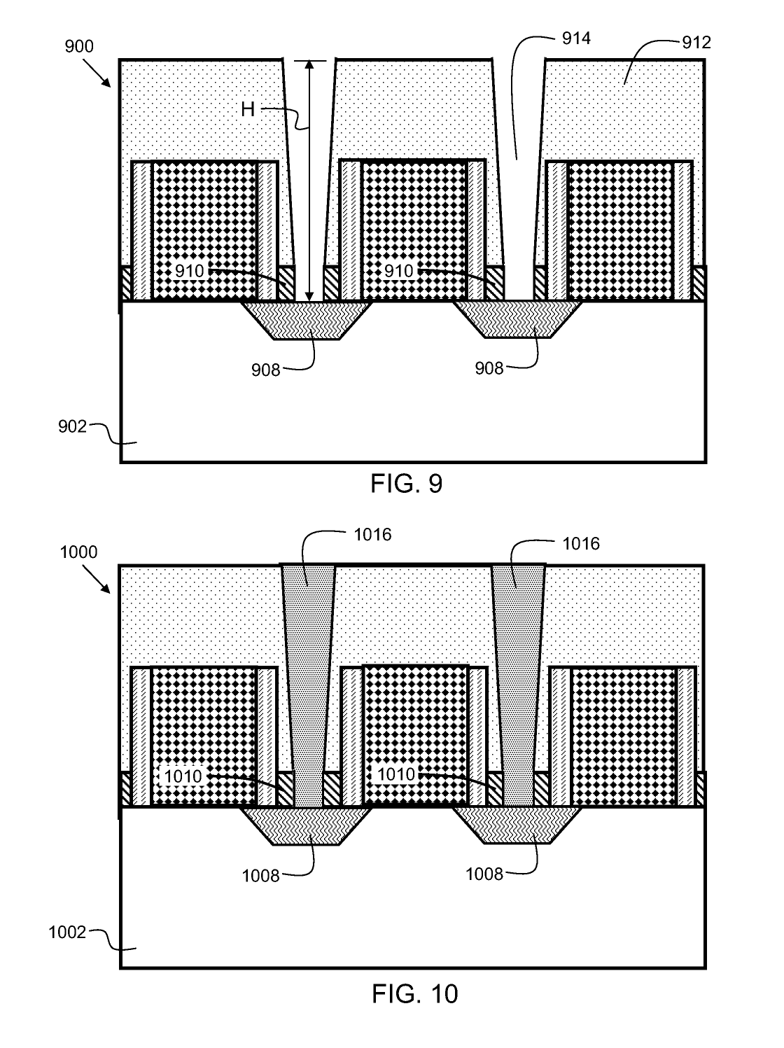

FIG. 9 is a semiconductor structure 900 after a subsequent process step of forming an opening in the contact etch stop layer 910, such that the contact cavities 914 extend through the interlayer dielectric material 912, and through the contact etch stop layer 910, and extend to source/drain regions 908, exposing the source/drain regions 908. The opening in the contact etch stop layer 910 is performed with a different etch process than the one used to form contact cavities 814 (of FIG. 8). In the embodiments, where contact etch stop layer 910 is comprised of silicon nitride, an etch process that etches silicon nitride is used. Similarly, in the embodiments, where contact etch stop layer 910 is comprised of hafnium oxide, an etch process that etches hafnium oxide is used. The contact cavities 914 have a height H. In embodiments, height H ranges from about 100 nanometers to about 130 nanometers. The minimum width of the contact etch cavities is less than W (FIG. 2), which may range from about 10 nanometers to about 20 nanometers. Therefore, in embodiments, the aspect ratio (H/W) of the contact cavities 914 is 5 or greater. In embodiments, the aspect ratio of height to width for the contact cavities 914 ranges from about 5 to about 10

FIG. 10 is a semiconductor structure 1000 after subsequent process steps of depositing a conductor in the contact cavity to form contacts 1016. A conductive material fills the contact cavities (914 of FIG. 9), and the contacts 1016 traverse the horizontally formed contact etch stop layer 1010. In embodiments, a metal is deposited, followed by a planarization process. The metal may be deposited by chemical vapor deposition (CVD) or other suitable technique. In embodiments, the planarization is performed with a chemical mechanical polish (CMP) process. In embodiments, the metal comprises tungsten. In other embodiments, aluminum or copper is used.

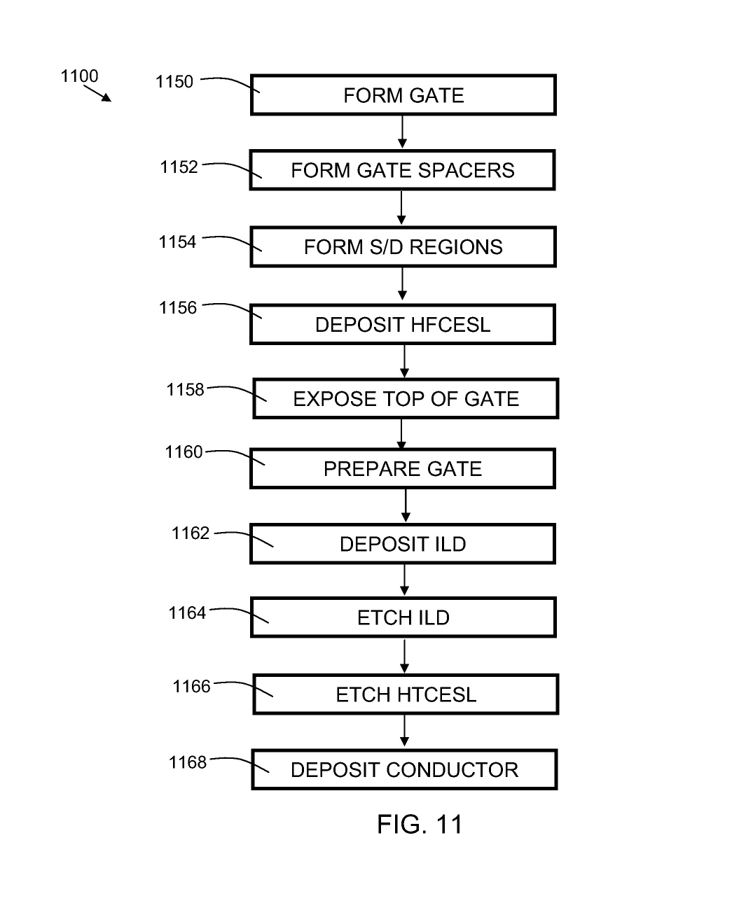

FIG. 11 is a flowchart 1100 indicating process steps for embodiments of the present invention. In process step 1150, a gate is formed on a semiconductor substrate. In process step 1152, gate spacers are formed on the gate. In process step 1154, source/drain regions are formed. In process step 1156, a horizontally formed contact etch stop layer (HFCESL) is deposited. In process step 1158, the structure is planarized and the tops of the gates are exposed (see 500 of FIG. 5). In process step 1160, the gate is prepared. In the case of a gate first process, the preparation may include forming a silicide layer on the gate. In the case of a replacement metal gate process, the polysilicon gate is removed and replaced with a metal gate (see 600 of FIG. 6). In process step 1162, an interlayer dielectric (ILD) is deposited. In process step 1164, the interlayer dielectric is etched (see 814 of FIG. 8). In process step 1166, the horizontally formed contact etch stop layer (HFCESL) is etched (see 914 of FIG. 9). In process step 1168, a conductor is deposited in the cavities to form contacts (see 1016 of FIG. 10).

Although the invention has been shown and described with respect to a certain preferred embodiment or embodiments, certain equivalent alterations and modifications will occur to others skilled in the art upon the reading and understanding of this specification and the annexed drawings. In particular regard to the various functions performed by the above described components (assemblies, devices, circuits, etc.) the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several embodiments, such feature may be combined with one or more features of the other embodiments as may be desired and advantageous for any given or particular application.

What is claimed is:

1. A semiconductor structure, comprising:
a semiconductor substrate;
a gate formed on the semiconductor substrate;
a source/drain region formed in the semiconductor substrate and disposed adjacent to the gate;
a spacer disposed on the gate;
a horizontally formed contact etch stop layer disposed on the source/drain region; and
a contact disposed on the source/drain region., wherein the contact traverses the horizontally formed contact etch stop layer.

2. The semiconductor structure of claim 1, wherein the horizontally formed contact etch stop layer is comprised of silicon nitride.

3. The semiconductor structure of claim 1, wherein the horizontally formed contact etch stop layer is comprised of hafnium oxide.

4. The semiconductor structure of claim 2, wherein the horizontally formed contact etch stop layer has a thickness ranging from about 3 nanometers to about 15 nanometers.

5. The semiconductor structure of claim 3, wherein the horizontally formed contact etch stop layer has a thickness ranging from about 4 nanometers to about 8 nanometers.

6. The semiconductor structure of claim 1, wherein the contact has an aspect ratio of height to width ranging from about 5 to about 10.

7. The semiconductor structure of claim 1, wherein the spacer is comprised of silicon oxide.

8. The semiconductor structure of claim 1, wherein the contact is comprised of tungsten.

9. A method of forming a semiconductor structure, comprising:
forming a gate on a semiconductor substrate;
forming spacers on the gate;
forming a source/drain region in the semiconductor substrate adjacent to the gate;
depositing a horizontally formed contact etch stop layer on the semiconductor structure;
depositing an interlayer dielectric material on the semiconductor structure;
forming a contact cavity in the interlayer dielectric material, wherein the contact cavity terminates at the contact etch stop layer;
forming an opening in the contact etch stop layer to expose the source/drain region; and
depositing a conductor in the contact cavity.

10. The method of claim 9, wherein depositing a horizontally formed contact etch stop layer on the semiconductor structure is performed using a gas cluster ion beam deposition process.

11. The method of claim 9, wherein depositing a horizontally formed contact etch stop layer on the semiconductor structure comprises depositing silicon nitride.

12. The method of claim 9, wherein depositing a horizontally formed contact etch stop layer on the semiconductor structure comprises depositing hafnium oxide.

13. The method of claim 11, wherein depositing silicon nitride comprises depositing a silicon nitride layer having a thickness ranging from about 3 nanometers to about 15 nanometers.

14. The method of claim 12, wherein depositing hafnium oxide comprises depositing a silicon nitride layer having a thickness ranging from about 4 nanometers to about 8 nanometers.

15. A method of forming a semiconductor structure, comprising:
forming a gate on a semiconductor substrate;
forming spacers on the gate, wherein the spacers have a vertical sidewall;
forming a source/drain region in the semiconductor substrate adjacent to the gate;
depositing a horizontally formed contact etch stop layer on the semiconductor structure using a gas cluster ion beam deposition process, wherein the horizontally formed contact etch stop layer is substantially flat, and does not adhere to the vertical sidewall of the spacers;
depositing an interlayer dielectric material on the semiconductor structure;
forming a contact cavity in the interlayer dielectric material, wherein the contact cavity terminates at the contact etch stop layer;
forming an opening in the contact etch stop layer to expose the source/drain region; and
depositing a conductor in the contact cavity.

16. The method of claim 15, wherein depositing a conductor in the contact cavity comprises depositing tungsten.

17. The method of claim 16, wherein depositing tungsten is performed via a chemical vapor deposition process.

18. The method of claim 15, wherein depositing a horizontally formed contact etch stop layer on the semiconductor structure comprises depositing silicon nitride.

19. The method of claim 15, wherein depositing a horizontally formed contact etch stop layer on the semiconductor structure comprises depositing hafnium oxide.

20. The method of claim 11, wherein depositing silicon nitride comprises depositing a silicon nitride layer having a thickness ranging from about 3 nanometers to about 15 nanometers, and a width ranging from about 15 nanometers to about 20 nanometers.
